(19) United States
(12) Patent Application Publication
(10) Pub. No.: US 2013/0027059 A1
(43) Pub. Date: Jan. 31, 2013

(54) Microwave reference block assembly

(71) Applicants: Scott Richard Breimon, Delano, MN (US); Matthew Whitlock Dawson, Saint Paul, MN (US); Teresa Ainsworth, Plymouth, MN (US); Darrell Thomas Butler, Austin, TX (US)

(72) Inventors: Scott Richard Breimon, Delano, MN (US); Matthew Whitlock Dawson, Saint Paul, MN (US); Teresa Ainsworth, Plymouth, MN (US); Darrell Thomas Butler, Austin, TX (US)

(73) Assignee: Thermo Fisher Scientific

(21) Appl. No.: 13/136,213

(22) Filed: Jul. 25, 2011

(51) Int. Cl. G01R 27/04

(52) U.S. Cl. 324/639

(57) ABSTRACT

A test waveguide (33) for evaluating the performance of microwave probe assemblies (1, 13) and their associated analysis equipment is mounted on a stand (56). The test waveguide (33) includes geometry that is similar to that found on the test cell assembly (2) used during commercial production activities. The test waveguide (33) includes an unsealed interior space (41) that remains accessible while the probe assemblies (1, 13) are fastened to the test waveguide. One or more reference blocks (59) are formed having known characteristics that permit calibration and evaluation of the probe assemblies and their associated analysis equipment. Each reference block (59) is manually inserted into the unsealed interior space (41) within the test waveguide (33) and the probe assemblies (1, 13) are activated to permit immediate evaluation of the accuracy of the probes and associated equipment

### FIELD OF THE INVENTION

This invention relates generally to the field of Guided Microwave Spectroscopy, and more particularly to calibration and testing assemblies.

### DESCRIPTION OF RELATED TECHNOLOGY

The use of a microwave waveguide cutoff frequency to characterize properties of materials is commonly referred to as Guided Microwave Spectroscopy (GMS) and is described, for example, in U.S. Pat. No. 5,331,284 (METER AND METHOD FOR IN SITU MEASUREMENT OF THE ELECTROMAGNETIC PROPERTIES OF VARIOUS PROCESS MATERIALS USING CUTOFF FREQUENCY CHARACTERIZATION AND ANALYSIS). In typical GMS implementations a flowing fluid or slurry material is continuously introduced into a chamber that is subject to microwave radiation. A microwave signal that has passed through the flowing material has altered characteristics when compared to the originally transmitted radio frequency energy, and a comparison of the transmitted and received signals permits certain properties of the material to be determined including most notably dielectric properties.

A typical GMS installation often exists in a food processing facility where the GMS equipment is installed more or less permanently as part of a relatively high speed production line in continuous operation. In order to verify that all GMS components are operating properly, the microwave components that actually irradiate the material under test should periodically test for correct operation. Since the material under test is typically a slurry or fluid that flows through a sealed conduit or pipeline, a calibrating material that would serve to verify proper operation would necessarily need to be in a liquid state and also flow through the food processing pipeline. This is inherently impractical for several reasons, including problems such as introducing a nonfood substance into food processing machinery, identifying an appropriate point in the system at which such calibrating fluids could be introduced, determining exactly when the calibration slurry enters and exits the measurement chamber, removing the calibrating slurry from the system, and creating, storing and transporting calibration slurries that would have truly homogeneous and known characteristics at the moment the slurry resides within the chamber. A need therefore exists for a convenient empirical method of verifying the proper functioning of the microwave exciting and receiving components in a GMS system with minimal disruption of the food processing operation.

### SUMMARY OF THE INVENTION

The present invention is a reference block system using a fixed, storable and easily transportable mass having known, constant dielectric properties. The reference block is suitably dimensioned to fit within a test waveguide that is substantially identical to the waveguide used in the production equipment that is being tested or calibrated. The use of a test waveguide eliminates the need to remove the actual production waveguide from the food processing line. Actual production equipment such as the microwave emitting probe and the microwave receiving probe are removed from the production waveguide and fastened to opposite sides of the test waveguide. The test waveguide is formed as a rectangular channel that forms a slot or opening into which a reference block may be manually inserted and removed. A set of reference blocks having differing dielectric properties may be inserted and removed from the test waveguide slot. This arrangement permits rapid testing of a production GMS device using all of the actual production components except for the production waveguide itself. The production waveguide is a relatively inert, rugged and massive structure which is unlikely to alter its characteristics even after prolonged use in an operating environment.

### BRIEF DESCRIPTION OF THE DRAWINGS

FIG. 1 is an isometric view of a guided wave spectroscopy measurement cell as used in a typical production environment

FIG. 2 is an isometric view of the measurement cell as shown in FIG. 1 with some of the components depicted in a spaced apart relationship;

FIG. 3 is an exploded view of the microwave probe assembly depicted in FIG. 2;

FIG. 4 is a top plan view of a reference stand and test waveguide constructed according to the principles of the present invention;

FIG. 5 is a front elevation view of the reference stand and test waveguide as depicted FIG. 4;

FIG. 6 is a side elevation view of the reference stand and test waveguide as depicted in FIG. 4;

FIG. 7 is an isometric view of the test waveguide depicted in FIG. 6;

FIG. 8 is an exploded isometric view of an enclosure that forms part of the present invention;

FIG. 9 is a detail drawing of the region 9 depicted in FIG. 8; and

FIG. 10 is an isometric view of a reference block that forms part of the present invention;

### DETAILED DESCRIPTION OF THE INVENTION

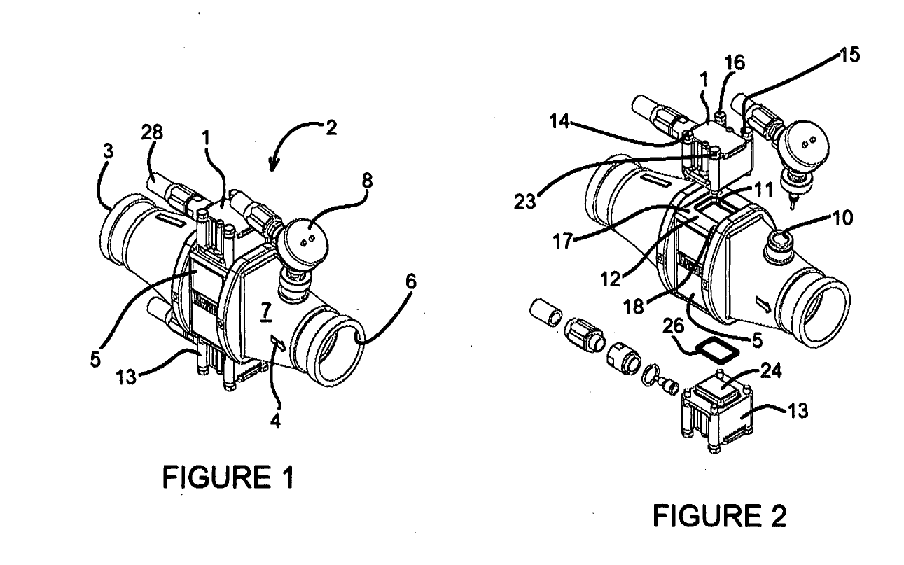

FIG. 1 depicts two examples 1 and 13 of a microwave probe assembly as they are typically affixed to a measurement cell assembly 2. The measurement cell assembly includes a generally rectangular test chamber or waveguide 5. A flowable material under test flows generally in the direction of arrow 4 through the test chamber 5. The material under test enters the measurement cell 2 at inlet 3 and exits at cell outlet 6. Referring also to FIG. 2, a transitional section 7 resides between the test chamber 5 and the outlet 6 and includes an orifice 10 formed to accept and retain a resistance temperature detector (RTD) assembly 8 which measures a temperature value within the material under test based on the current or voltage variation through an electrical conductor such as a platinum coil.

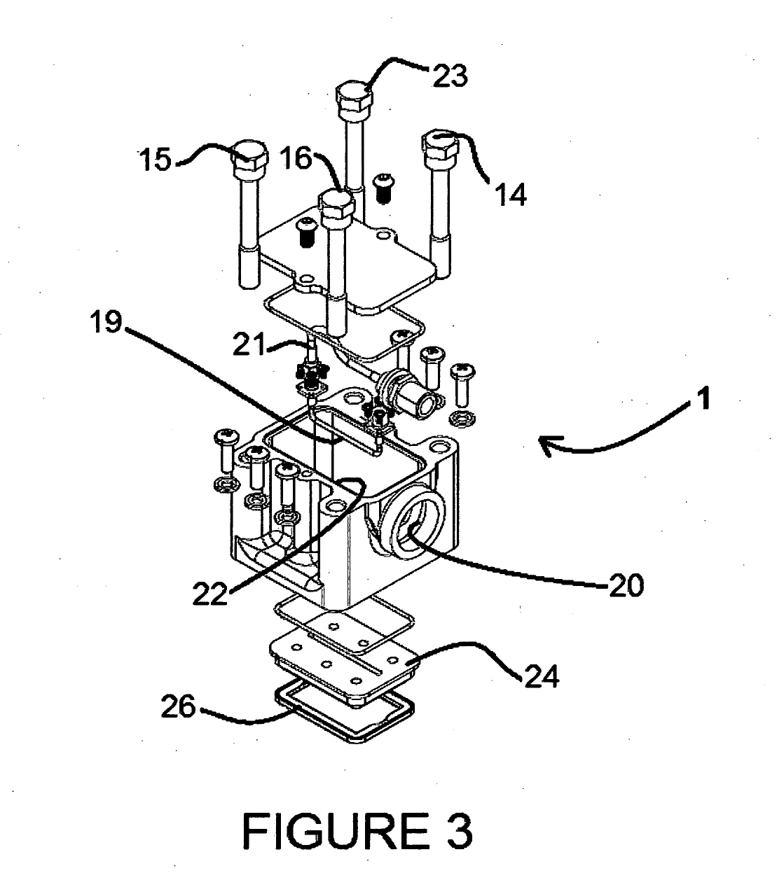

The chamber or waveguide 5 includes a generally rectangular opening 11 which permits access to material flowing through the chamber. The probe assembly 1 is mounted onto the generally planar surface 12 of the chamber or waveguide 5 by means of four captive bolts 23, 14, 15 and 16 which are retained by mating orifices, such as orifices 17 and 18, formed within the planar surface 12. Referring also to FIG. 3, the probe assembly 1 includes an antenna 19 which is interconnected to a microwave emitter that is accessed by a coaxial cable 21 which enters the probe assembly 1 via a conduit assembly 28 which passes through orifice 20. The antenna 19 emits a microwave signal into the interior region 22 of the chamber 5 through a microwave transparent process seal 24 and gasket 26. The location of the antenna 19 causes any material flowing through the chamber or waveguide 5 to be irradiated by the emitted microwave radiation. The substantially identical probe assembly 13 is mounted in an opposed relationship to the probe assembly 1. The antenna within the probe assembly 13 receives the emitted signal originating from the probe assembly 1. Ideally the material under test flowing through the chamber 5 alters the emitted signal in a manner that permits at least some characteristics of the flowing material under test to be discerned from subsequent analysis of the signal received by probe assembly 13.

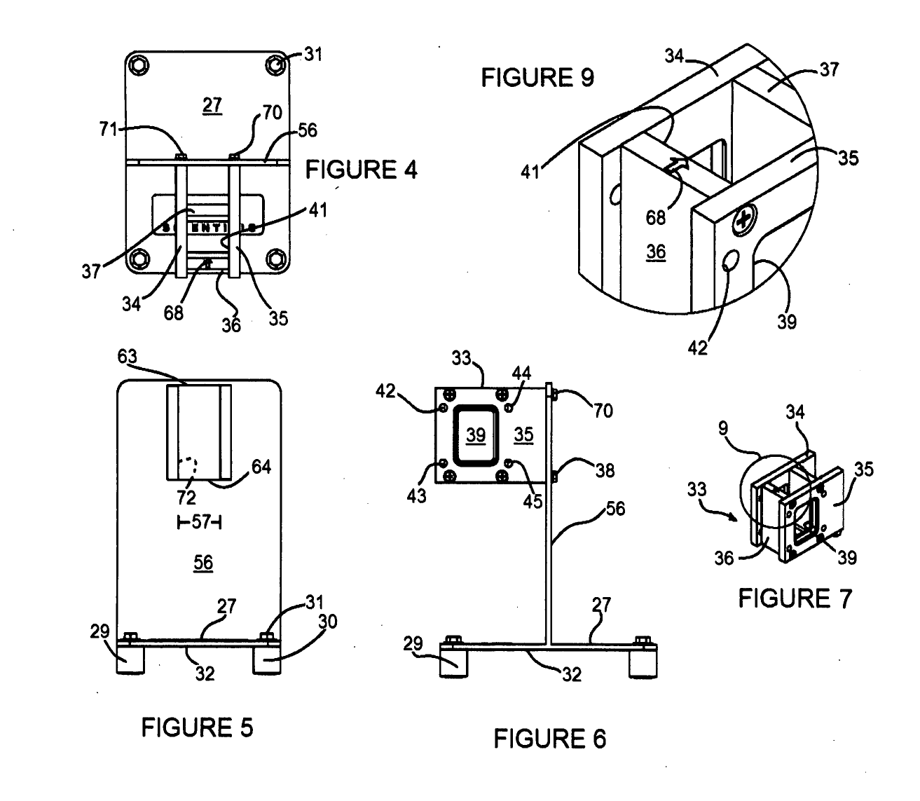

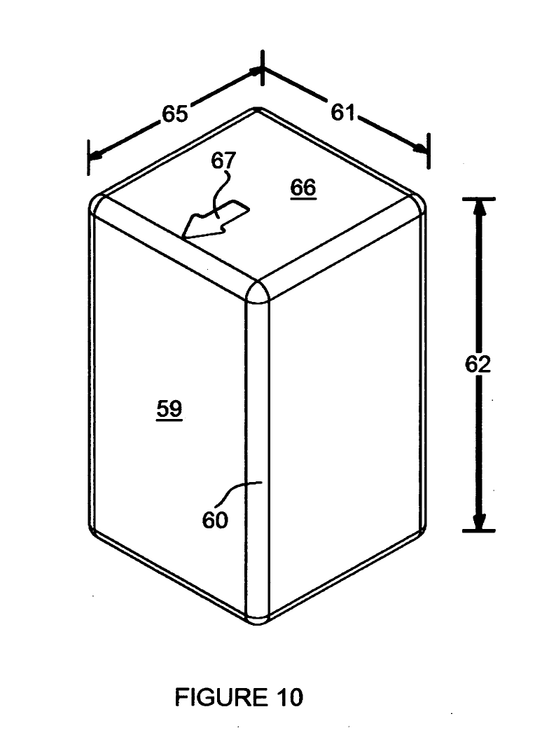

In order to verify proper operation of the foregoing apparatus, a reference assembly 25 constructed in accordance with the principles of the present invention is shown in FIG. 4. The reference assembly 25 includes a planar horizontally oriented base 27 which supports a substantially orthogonal plate or stand 56. As seen in FIG. 5, attached to the base 27 are bolts 31 which secure four feet such as feet 29 and 30, for example, to the bottom surface 32 of the base. The plate or stand 56 serves as the support for a test waveguide 33 as best seen in FIGS. 6, 7 and 9. The test waveguide 33 is formed to include a left sidewall 34 and a right sidewall 35 which are held in a parallel, spaced apart relationship by front plate 36 and rear plate 37. The structural combination of the left sidewall 34, the right sidewall 35, the front plate 36 and the rear plate 37 define the electromagnetic boundary of the test waveguide 33. The left and right sidewalls 34 and 35 are affixed to the stand 29 by means of bolts passing through the stand, such as, for example, bolts 71, 70 and 38, that are threaded into mounting bores formed within the sidewalls.

The left and right sidewalls 34 and 35 are each formed with a generally rectangular orifice 39 and 40, respectively, so as to create a horizontally aligned, unsealed access path to the interior space 41 residing between the two sidewalls. Each sidewall 34 and 35 also includes mounting bores 42, 43, 44 and 45 which are suitably oriented and dimensions so as to align with the position of bolts 14, 15, 16 and 23 of the probe assembly 1.

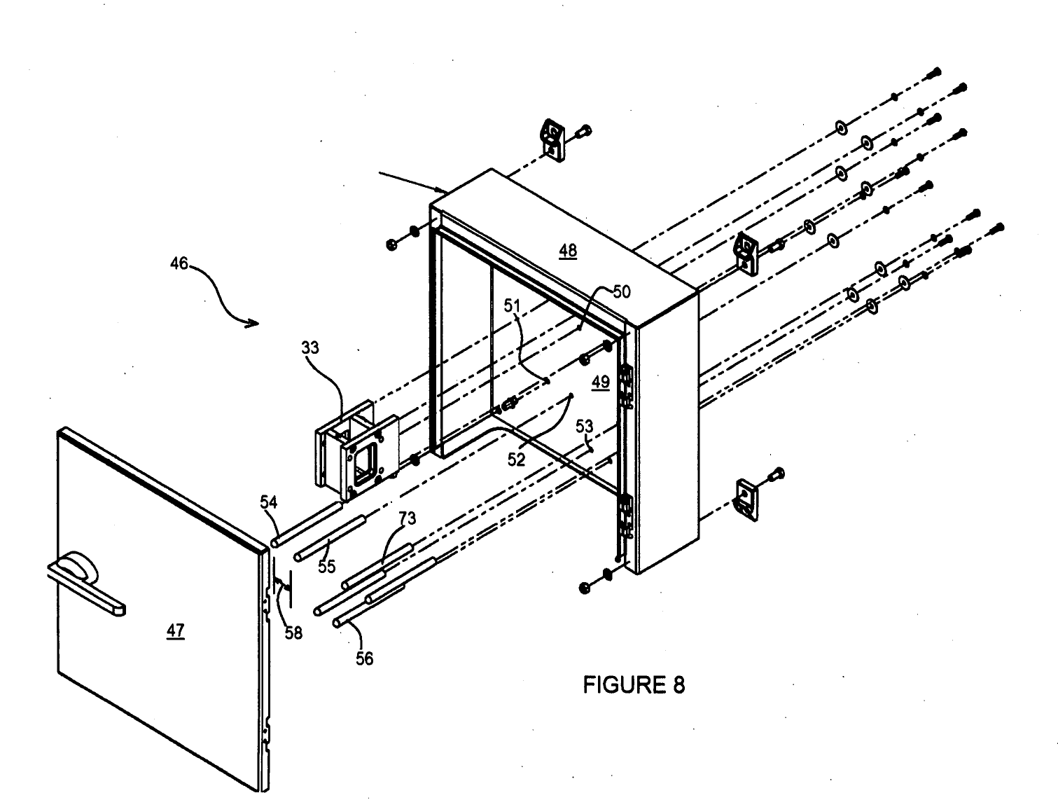

In an alternate embodiment of the present invention illustrated in FIG. 8, the test waveguide 33 is mounted within an enclosure 46 which includes a hinged door 47 and a generally rectangular housing 48. Formed within the substantially planar rear wall 49 of the housing 48 are a plurality of mounting holes, such as mounting hole 50, for example, which are aligned with the mounting bores of the sidewalls 34 and 35. In this manner the test waveguide 33 is rigidly affixed to the rear wall 49 and the sidewalls 34 and 35 assume a substantially vertical orientation.

Additional mounting holes, such as mounting holes 51, 52 and 53, for example, are also formed within the rear wall 49 to permit mounting of various support pegs or rods, such as, for example, rods 54, 55, 56 and 73. When mounted on the rear wall 49 the rods, such as rods 54, 55, 56 and 73, assume a rigid, substantially orthogonal relationship to the planar rear wall 49. The rods, such as rods 54 and 55, are typically mounted as a spaced apart pair, separated by a distance 58 which is selected to permit a probe assembly, such as probe assembly 1, to rest on the rods 54 and 55. The enclosure 46 is preferably mounted so that the rear wall 49 is substantially vertical, thereby causing the rods 54 and 55 to assume a substantially horizontal orientation.

Regardless of whether the test waveguide 33 is mounted within the enclosure 46 or to the plate or stand 56, the test waveguide is rigidly supported so that the left sidewall 34 and the right sidewall 35 reside in a substantially vertical plane. The sidewalls 34 and 35 are separated by a distance 57 to form a test waveguide 33 which has electromagnetic characteristics that are substantially identical to the actual waveguide 5 used on a measurement cell assembly 2 as found on a typical production line. Unlike the measurement cell assembly 2, the test waveguide 33 forms an open vertical channel 72 into which a calibrated reference mass, such as the reference block 59 depicted in FIG. 10, may be inserted and removed. The reference block is composed of a rigid epoxy based magnetic microwave absorbing material with the addition of a secondary material to achieve the desired dielectric or attenuation characteristics. Such materials may be obtained from Resin Systems Corporation located in Amherst, N.H. The reference block 59 is formed a substantially rectangular solid having radiused edges 60. The width 61 and depth 65 is approximately 1.875 inches and somewhat less than the spacing 57 of the test waveguide sidewalls 34 and 35, thereby permitting insertion of the reference block 59 into the test waveguide 33. The height 62 of the reference block is approximately 3.25 inches, thereby permitting the block 59 to fit entirely within the test waveguide 33 and be substantially aligned or flush with the top edge 63 and the bottom edge 64 of the waveguide. An orientation arrow 67 is placed on the top surface 66.

In operation, a user of the present invention detaches each of the probe assemblies 1 and 13 from the test cell assembly 2 with the conduit assemblies 28 of each probe assembly still attached to any instrumentation that is normally used during actual commercial production. Each of the probe assemblies 1 and 13 are then rigidly mounted to either sidewall 34 and 35 of the test waveguide 33 by inserting the captive bolts 14, 15, 16 and 23 into the mounting holes 42, 43, 44 and 45 on each sidewall. By affixing the probe assemblies 1 and 13 to the sidewalls 34 and 35, the horizontally aligned unsealed access path becomes an electromagnetically sealed transmission and reception path between the probe assemblies 1 and 13.

The user then chooses a desired reference block 59 based on the dielectric properties of that particular block. Typically a reference block 59 is chosen that has properties similar to those of the proposed material under test flowing through the actual test cell assembly 2. The user orients the reference block 59 above the top edge 63 of the test waveguide 33 so that the arrow 67 on the reference block is aligned with the arrow 68 marked on the top surface 69 of the front plate 36. The reference block is then momentarily lowered into the space 41 within the test waveguide 33 and the probe assemblies 1 and 13 are activated. The instrumentation normally used during actual commercial production is then consulted to determine if the analysis matches the characteristics of the reference blocks. When complete, the probe assemblies 1 and 13 may then be removed from the test waveguide 33 and promptly reattached to the test cell assembly 2 in order that production operations may be resumed.

While the invention has been described with reference to the preferred embodiments, various modifications to the foregoing concept of an easily installable and removable clean in place probe assembly may be readily envisioned. For example, the specific structure used to mount the waveguide may be altered as is convenient in any particular commercial setting. In some cases the vertical orientation of the sidewalls 34 and 35 may be abandoned to accommodate the convenience of the user. Further, the test waveguide 33 may have differing physical dimensions based on variations in operational equipment, whereas the physical dimensions of the reference block 59 will typically remain the same since the reference block is still able to fit within the test waveguide. Other modifications may be practiced by those skilled in this field without departing from the scope of the claims.

We claim:

1. A reference block system adapted to evaluate accuracy and performance of a guided microwave spectroscopy device including a pair of probe assemblies that are normally affixed to an operational waveguide, comprising:
(a) a test waveguide, the test waveguide having electromagnetic characteristics that are substantially similar to electromagnetic characteristics of the operational waveguide in the guided microwave spectroscopy device;
(b) a mounting fixture, the mounting fixture being adapted to support the test waveguide; and
(c) at least one calibrated reference mass, the calibrated reference mass being insertable into the test waveguide while the guided microwave spectroscopy device is operational.

2. The reference block system of claim 1, wherein the test waveguide further comprises:
(a) a horizontally aligned unsealed access path, the unsealed access path providing electromagnetic access between a microwave emitter and a microwave receiver; and
(b) an open vertical channel, the open vertical channel being substantially orthogonal to the horizontally aligned unsealed access path, the open vertical channel permitting introduction of the calibrated reference mass into the test waveguide.

3. The reference block system of claim 2, wherein the test waveguide further comprises:
(a) a left sidewall, the left sidewall being formed as a planar member that includes a first generally rectangular orifice; and
(b) a right sidewall, the right sidewall being formed as a planar member that includes a second generally rectangular orifice, the left sidewall and the right sidewall being substantially parallel.

4. The reference block system of claim 3, wherein the left sidewall and the right sidewall are substantially identical.

5. The reference block system of claim 4, wherein the test waveguide further comprises:
(a) a front plate; and
(b) a rear plate, the front plate and the rear plate each being rigidly affixed to the right sidewall and the left sidewall so as to retain the left sidewall and the right sidewall in a fixed, space apart parallel relationship, the front plate, the rear plate, the left sidewall and the right sidewall thereby defining an electromagnetic boundary of the test waveguide.

6. The reference block system of claim 5, further comprising a reference stand, the test waveguide being rigidly affixed to the reference stand.

7. The reference block system of claim 6, wherein the reference stand secures the test waveguide in an orientation that causes the left sidewall and the right sidewall to be substantially vertical.

8. The reference block system of claim 7, wherein a first one of the pair of probe assemblies is affixed to the left sidewall and a second one of the pair of probe assemblies is affixed to the right sidewall, thereby electromagnetically sealing the horizontally aligned unsealed access path of the test waveguide.

9. The reference block system of claim 8, wherein the calibrated reference mass is formed as a substantially rectangular solid being suitably dimensioned to be insertable within the open vertical channel of the test waveguide.

10. The reference block system of claim 9, wherein the reference block further comprises:
(a) a substantially planar top surface;
(b) an arrow graphic inscribed on the substantially planar top surface, the arrow graphic being aligned with a mark on the test waveguide when the reference block is properly inserted into the open vertical channel of the test waveguide.

11. The reference block system of claim 10, wherein the reference block further comprises:
(a) a rigid epoxy based magnetic microwave absorbing material; and
(b) a secondary material added to achieve desired dielectric characteristics.

12. The reference block system of claim 11, further comprising a plurality of individual reference blocks, wherein each of the plurality of individual reference blocks has a dielectric characteristic that differs from all others of the plurality of individual reference blocks, thereby permitting a user of the reference block system to evaluate performance of the guided microwave spectroscopy device over a range of potential dielectric values.

13. A performance evaluation system for a microwave transmitter and receiver that is mounted on a production waveguide which is a component of a signal analysis apparatus that analyzes material flowing in a fluid carrying conduit, comprising:
(a) a plurality of reference blocks, each reference block having a known and substantially constant dielectric characteristic; and
(b) a test waveguide, the test waveguide being mounted on a test fixture, the microwave transmitter and receiver being mounted on the test waveguide after removal from the production waveguide and while still interconnected to a remainder of the signal analysis apparatus, the test waveguide being adapted to house one of the plurality of reference blocks while the transmitter and receiver are energized, thereby permitting evaluation of the remainder of the signal analysis apparatus.

14. The performance evaluation system of claim 13, wherein the test fixture is formed as an enclosure, the enclosure comprising:
(a) a hinged door; and
(b) a generally rectangular housing having a substantially planar rear wall, the test waveguide being rigidly affixed to the rear wall while the test waveguide is attached to the microwave transmitter and receiver.

15. The performance evaluation system of claim 14, wherein the test waveguide comprises an open vertical channel, the open vertical channel permitting manual insertion and removal of one of the plurality of reference blocks into a path residing between the microwave transmitter and receiver when the microwave transmitter and receiver are affixed to the test waveguide.

16. The performance evaluation system of claim 15, wherein electromagnetic properties of the test waveguide are substantially similar to electromagnetic characteristics of the production waveguide.

17. The performance evaluation system of claim 16, wherein the test waveguide further comprises:
(a) a left sidewall, the left sidewall being formed to include a substantially rectangular orifice; and
(b) a right sidewall, the right sidewall being substantially identical to the left sidewall, the left and right sidewall being secured in a substantially parallel spaced apart relationship such that both of each substantially rectangular orifice are horizontally aligned with each other so to create the path residing between the microwave transmitter and receiver when the microwave transmitter and receiver are affixed to the test waveguide.

18. A method of evaluating performance of a device adapted to determine at least some characteristics of a flowing material within a conduit mounted waveguide by comparing a received signal with a transmitted signal that has propagated through the flowing material within the conduit mounted waveguide, comprising the steps of:
(a) mounting a test waveguide on a test fixture;
(b) removing a signal transmitter and a signal receiver from the conduit mounted waveguide;
(c) remounting the signal transmitter and the signal receiver onto the test waveguide;
(d) inserting a calibrated reference mass into the test waveguide;
(e) activating the signal transmitter and the signal receiver while the calibrated reference mass resides within the test waveguide; and
(f) evaluating performance of the device to determine if the device is operating properly.

19. The method of claim 18, further comprising the steps of:
(a) forming the test waveguide to include an open vertical channel;
(b) manually inserting a first calibrated reference mass into the open vertical channel;
(c) evaluating the performance of the device with the first calibrated reference mass residing within the open vertical channel;
(d) removing the first calibrated reference mass from the open vertical channel;
(e) inserting a second calibrated reference mass into the open vertical channel; and
(f) evaluating the performance of the device with the second calibrated reference mass residing within the open vertical channel.

20. The method of claim 19, further comprising the steps of:
(a) removing the signal transmitter and the signal receiver from the test waveguide upon completion of evaluation of the device; and
(b) remounting the signal transmitter and the signal receiver onto the conduit mounted waveguide so as to enable the device to resume determination of characteristics of a material flowing within the conduit mounted waveguide.
